(19) United States
(12) Patent Application Publication
(10) Pub. No.: US 2026/0025945 A1
(43) Pub. Date: Jan. 22, 2026

(54) THERMAL MANAGEMENT SYSTEM FOR SWITCHGEAR ENCLOSURE

(71) Applicant: Eaton Intelligent Power Limited, Dublin 4 (IE)

(72) Inventors: Sarthak Shah, Pune (IN); Sarang Sarode, Pune (IN); Tejas B. Shinde, Pune (IN); Ravindra Tukaram Rikame, Nashik (IN); Jared Hines, Greenwood, SC (US); Lalit Patil, Greenwood, SC (US); Shivayogi Salutagi, Pune (IN); Amit Ashok Khendad, Pune (IN)

(21) Appl. No.: 18/776,721

(22) Filed: Jul. 18, 2024

(51) Int. Cl. H05K 7/20

(52) U.S. Cl. CPC H05K 7/20209; H05K 7/20145

(57) ABSTRACT

A thermal management system for a switchgear enclosure configured to house electrical components is disclosed. The system can include a swing flap positioned at an opening on the switchgear enclosure, configured to move between a first position, allowing airflow, and a second position, restricting airflow. The system includes an airflow component, positioned between the electrical components and the swing flap, to facilitate airflow introduction, passage, and exit through the switchgear enclosure. The swing flap moves to the second position in response to arc fault pressure, reducing a likelihood of escape of arc fault byproducts. The presence of the swing flap can create a non-linear airflow path from the opening to the airflow component such that the airflow is directed around the swing flap.

### FIELD

The present disclosure generally relates to thermal management systems for electrical switchgear and, more particularly, to heat dissipation in switchgear enclosures.

### BACKGROUND

Switchgear enclosures in electrical power distribution systems house components such as circuit breakers, isolating switches, and busbars. Managing the operating temperatures within these enclosures can be important, especially with higher continuous current ratings. Increased current leads to thermal losses, causing temperature rises that could affect the performance and safety of the switchgear.

Switchgear designed to meet specific safety standards often has fully enclosed structures to contain and mitigate arc faults. This design restricts natural airflow, making heat dissipation challenging. Efficient thermal management within these constraints, especially in compact designs that aim to minimize footprint while increasing current capacity, has been difficult to achieve.

### SUMMARY

Certain illustrative examples are described in the following numbered clauses:

Clause 1. A thermal management system for a switchgear enclosure configured to house electrical components, comprising:
a swing flap positioned at an opening on the switchgear enclosure, the swing flap configured to move between a first position in which the opening is unobstructed by the swing flap to thereby allow airflow through the opening, and a second position in which the opening is obstructed by the swing flap to thereby restrict airflow through the opening; and
first and second airflow components, each positioned between the electrical components and the swing flap, wherein at least one of the first or second airflow components facilitate an introduction of airflow into the switchgear enclosure through the opening, passage of the airflow through the electrical components, and exit of the airflow from the switchgear enclosure through the opening,
wherein the swing flap is configured to move to the second position responsive to pressure generated by an arc fault within the switchgear enclosure, thereby reducing a likelihood of escape of arc fault byproducts from the switchgear enclosure.

Clause 2. The system of clause 1, wherein the swing flap is normally biased to the first position by gravitational force, thereby allowing airflow through the opening under normal operating conditions.

Clause 3. The system of any of the previous clauses, wherein the exit of the airflow from the switchgear enclosure through the opening occurs via another airflow component.

Clause 4. The system of any of the previous clauses, wherein the swing flap is normally biased to a second-position, and wherein the swing flap is configured to be pulled to the first position by the airflow generated by the first and second airflow components, thereby allowing airflow through the opening under normal operating conditions.

Clause 5. The system of any of the previous clauses, wherein the swing flap comprises a first swing flap and a second swing flap, and the opening comprises a first opening and a second opening, wherein the first swing flap is positioned at the first opening and the second swing flap is positioned at the second opening.

Clause 6. The system of clause 5, wherein the first airflow component is mechanically aligned with the first swing flap and the first opening, and the second airflow component is mechanically aligned with the second swing flap and the second opening.

Clause 7. The system of any of clauses 5 to 6, wherein the first airflow component is configured to facilitate the introduction of airflow into the switchgear enclosure through the first opening, and the second airflow component is configured to facilitate the exit of airflow from the switchgear enclosure through the second opening.

Clause 8. The system of any of clauses 5 to 7, wherein the first and second openings are sized to maintain a balanced inlet-to-outlet airflow ratio, thereby reducing a likelihood of pressure buildup or backpressure within the switchgear enclosure.

Clause 9. The system of any of clauses 5 to 8, wherein the first and second swing flaps are mechanically linked to move dependently, facilitating synchronized movement into the second position.

Clause 10. The system of any of clauses 5 to 9, wherein the first airflow component comprises a fan configured to introduce the airflow into the switchgear enclosure and the second airflow component comprises an aperture configured to allow the airflow to pass from the electrical components to the second opening.

Clause 11. The system of any of the previous clauses, wherein in the first position the swing flap is oriented at an angle between 20 and 40 degrees relative to a plane of the opening.

Clause 12. The system of any of the previous clauses, wherein the switchgear enclosure has a continuous current rating of up to 3150 A.

Clause 13. The system of any of the previous clauses, wherein the switchgear enclosure has a width between 500 mm and 800 mm.

Clause 14. The system of any of the previous clauses, wherein the system is a gas insulated switchgear (GIS) system, wherein the electrical components comprise at least one heat producing component positioned within the switchgear enclosure, and wherein the at least one heat producing component comprises a vacuum interrupter, a copper conductor, or a canted contact spring.

Clause 15. The system of any of the previous clauses, further comprising a third airflow component positioned between the electrical components and the swing flap, wherein the third airflow component further facilitates the introduction of airflow into the switchgear enclosure through the opening, the passage of the airflow through the electrical components, and the exit of the airflow from the switchgear enclosure through the opening.

Clause 16. A thermal management system for a switchgear enclosure configured to house electrical components, comprising:
a plurality of swing flaps positioned at corresponding openings on the switchgear enclosure, each swing flap being movable between a first position, which allows unobstructed airflow through its respective opening, and a second position, which restricts airflow through its respective opening, the swing flaps being normally in the first position;
a plurality of airflow components positioned between the electrical components and the swing flaps, the airflow components facilitating an entry of airflow into the switchgear enclosure through a first opening of the openings, directing the airflow through the electrical components, and facilitating an exit of the airflow from the switchgear enclosure through a second opening of the openings;
wherein the swing flaps are mechanically linked such that each swing flap moves in unison to the second position in response to pressure generated by an arc fault within the switchgear enclosure, thereby reducing a likelihood of arc fault byproducts escaping from the switchgear enclosure.

Clause 17. The system of clause 16, wherein only one of the plurality of airflow components is active at a time to introduce airflow into the switchgear enclosure.

Clause 18. A thermal management system for a switchgear enclosure including an opening for airflow and configured to house electrical components, comprising:
at least one airflow component positioned to facilitate introduction and movement of the airflow within the switchgear enclosure;
at least one swing flap positioned between the opening and the airflow component, the swing flap configured to move between a first position in which the swing flap is positioned to create a non-linear airflow path from the opening to the airflow component such that the airflow is directed around the swing flap, and a second position in which the opening is obstructed by the swing flap to thereby restrict airflow through the opening,
wherein the non-linear airflow path delays escape of arc fault byproducts from the switchgear enclosure by requiring the byproducts to navigate around the swing flap, providing additional time for the swing flap to move to the second position in response to pressure from the arc fault.

Clause 19. The system of clause 18, wherein the swing flap is pivotally connected to the switchgear enclosure proximate the opening, and is configured to pivot between the first and second positions, and wherein the swing flap is in the first position under normal operating conditions.

Clause 20. The system of clause 19, wherein the swing flap is oriented at an angle between about 20 degrees and about 40 degrees relative to a plane of the opening.

### BRIEF DESCRIPTION OF THE DRAWINGS

Throughout the drawings, reference numbers can be re-used to indicate correspondence between referenced elements. The drawings are provided to illustrate embodiments of the present disclosure and do not limit the scope thereof.

FIG. 1 illustrates a prior art switchgear enclosure.

FIG. 2 illustrates a schematic diagram of an example thermal management system within a switchgear enclosure in accordance with some aspects of the inventive concepts.

FIG. 3 illustrates a side internal view of an implementation of an example thermal management system within the switchgear enclosure.

FIG. 4 illustrates a front internal view of the switchgear enclosure of FIG. 3.

### DETAILED DESCRIPTION

Managing the operating temperatures within switchgear enclosures can be an important aspect for ensuring reliable performance and safety in electrical power distribution systems. Traditional thermal management methods, such as natural convection, might be insufficient, particularly as current ratings increase and designs become more compact. This challenge is compounded in fully enclosed switchgear, designed to meet safety standards for internal arc fault (IAF) resistance, thereby limiting natural airflow and complicating heat dissipation.

Some inventive concepts described herein can improve the thermal management of switchgear enclosures by integrating a thermal management system that includes strategically placed fans and dynamically operated swing flaps. These components can work together to improve heat dissipation from electrical components such as vacuum interrupters and copper conductors, allowing the switchgear to operate within desired thermal limits.

Some inventive concepts described herein relate to a thermal management system that includes first and second airflow components, each positioned to facilitate the introduction of airflow into the switchgear enclosure and the passage of airflow through the electrical components. A swing flap can be positioned at an opening on the switchgear enclosure and can be configured to move between an open position, allowing airflow, and a closed position, restricting airflow in response to pressure generated by an arc fault. This design can reduce the likelihood of escape of arc fault byproducts, thereby improving safety.

Some inventive concepts described herein relate to mechanisms for maintaining balanced airflow and pressure within the switchgear enclosure. For example, the swing flaps can be normally biased to an open position to allow natural airflow but can move to a closed position in response to arc fault pressure. This balance can be achieved through the use of gravitational forces and strategically aligned airflow components that ensure effective cooling during normal operation and protection during fault conditions.

Some inventive concepts described herein relate to redundant airflow components to facilitate continuous operation, even if one component fails. This redundancy can improve the reliability of the thermal management system, allowing the switchgear to maintain desired operating temperatures over extended periods while reducing a likelihood of interruption.

The described thermal management systems represent an improvement in the field of electrical switchgear, particularly in managing heat within compact, fully enclosed designs. By enabling enhanced airflow and integrating responsive safety mechanisms, these inventive concepts ensure that switchgear can handle current ratings up to 3150 A or higher. The disclosed techniques can allow for efficient thermal regulation, reduced risk of overheating, and/or improved operational lifespan of the switchgear components.

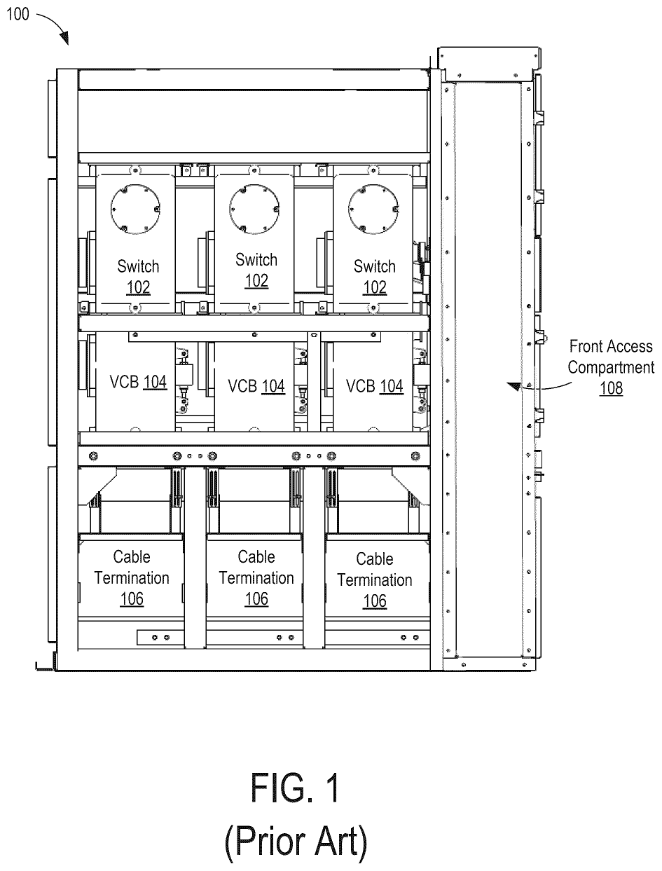

FIG. 1 illustrates a prior art switchgear enclosure 100, configured to house electrical components such as circuit breakers, isolating switches, and busbars, isolating switches, vacuum interrupter, or cable termination. The switchgear enclosure 100 can include one or more switches 102, one or more vacuum circuit breakers (VCB) 104, and/or one or more cable terminations 106. The switchgear enclosure 100 can include a front access compartment 108. The enclosure 100 can be designed as a fully enclosed structure that meets particular safety standards, such as Internal Arc Fault (IAF) Type 2B rating as per IEEE C37.20.9.

The switchgear enclosure 100 can house vacuum interrupters, which can be heat-generating components; isolating switches, which can be connected to a busbar compartment that includes busbars; or vent openings for natural convection cooling, among other things.

The design of the switchgear enclosure 100 can rely on natural convection and enhanced thermal conductivity of external parts to manage heat dissipation. However, due to the fully enclosed structure and compact design, it faces challenges in dissipating heat effectively, particularly at higher continuous current ratings of up to 3150 A. This limitation can result in increased thermal losses (I²R) and elevated temperatures within the switchgear enclosure 100, potentially compromising the performance and safety of the electrical components.

### Example Thermal Management System

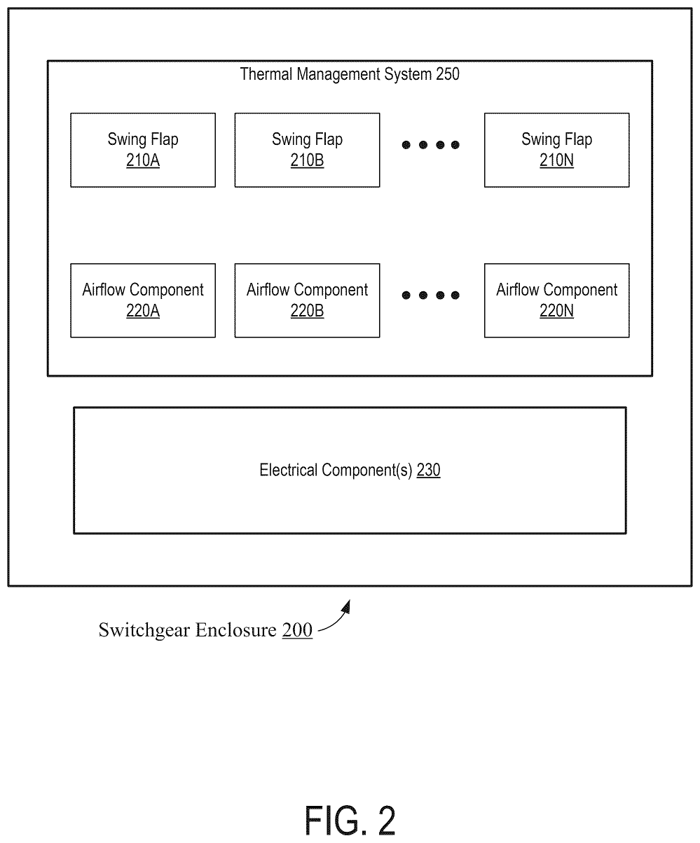

FIG. 2 illustrates a schematic diagram of an example thermal management system 250 within a switchgear enclosure 200 in accordance with some aspects of the inventive concepts. The thermal management system 250 can include at least one swing flap 210A, 210B, . . . 210N (individually or collectively referred to as swing flap 210 or swing flaps 210) and at least one airflow component 220A, 220B, . . . 220N (individually or collectively referred to as airflow component 220 or airflow components 220). The switchgear enclosure 200 can include one or more electrical components 230.

The switchgear enclosure 200 can be configured to house various electrical components 230, which can include, but are not limited to, circuit breakers, busbars, vacuum interrupters, copper conductors, canted contact springs, flexible copper conductors, or 3-position isolating switches (3PS). The electrical components 230 can be sources of heat within the switchgear enclosure 200. Effective thermal management can be important to maintain the reliability and performance of these components, especially under high current conditions.

The thermal management system 250 can improve the efficiency and safety of the switchgear enclosure 200 by effectively managing heat dissipation. In this way, the switchgear enclosure 200 can achieve an increased continuous current rating relative to conventional designs. For example, the switchgear enclosure 200 can have a continuous current rating of X, where X can be about 1500A, about 2000A, about 2500A, about 3000A, about 3150A, or higher. In some cases, the switchgear enclosure 200 can have a width to fit various installation spaces. For example, the width of the switchgear enclosure 200 can be up to Y mm, where Y can be about 400 mm, about 450 mm, about 500 mm, about 550 mm, about 600 mm, about 650 mm, or about 700 mm.

The electrical components 230 may operate in normal operating conditions or fault conditions. In some cases, normal operation can refer to standard, everyday functioning without any electrical faults, where the electrical components 230 can operate within its designed parameters, maintaining stable temperatures within the switchgear enclosure 200. During normal operation, the electrical components 230 can function as intended, facilitating airflow and thermal management without the presence of any anomalies or disturbances. In some cases, a fault condition can refer to a situation that can disrupt normal operations, such as arc faults. Arc faults can occur due to various reasons, including, but not limited to, equipment failure, insulation breakdown, or accidental short circuits. A fault condition can generate excess pressure and hazardous byproducts, such as intense heat, ionized gases, or molten materials. The presence of such byproducts can pose significant safety risks if not properly contained and managed.

The swing flaps 210 can provide dynamic and responsive airflow management within the switchgear enclosure 200, thereby improving the integrity of the switchgear enclosure 200 during normal operation and fault conditions. The swing flaps 210 can be positioned at or proximate to openings in the switchgear enclosure 200. These openings can be strategically placed vents or apertures designed to facilitate the flow of air into and out of the switchgear enclosure 200. By being located at or near these openings, the swing flaps 210 can regulate airflow, facilitating the maintenance of thermal conditions within the switchgear enclosure 200.

A swing flap 210 can be movable between a first position and a second position, facilitating dynamic airflow management within the switchgear enclosure 200. In the first position (sometimes referred to as an “open” position), the swing flaps 210 can allow cool air to enter the switchgear enclosure 200 and/or hot air to escape, aiding in heat dissipation. This airflow helps maintain desired operating temperatures for the electrical components 230 during normal conditions. In some cases, a swing flap 210 can be connected to the switchgear enclosure 200 via hinges, allowing it to pivot between the first and second positions. In some cases, gravity can cause the swing flap 210 to remain open during normal operation. For instance, the swing flap 210 may be positioned at or near the top portion of the switchgear enclosure 200, and the swing flap 210 can hang down in the open position. In some cases, the open position, the swing flap is oriented at an angle, X, relative to a 2D plane of the opening, where X is about 10, 15, 20, 25, 30, or 35 degrees (+/−a few degrees), or where X is between about 10 degrees and about 40 degrees, or between about 20 degrees and 30 about degrees relative to the 2D plane of the opening.

In the second position (sometimes referred to as a “closed” position), the swing flaps 210 can at least partially restrict airflow, which can be particularly useful in containing hazardous byproducts during fault conditions, such as arc faults. As described herein, in some cases, the swing flaps 210 can be configured to quickly close during fault conditions. For example, the pressure generated by an arc fault can force the flaps to move (e.g., pivot) to the closed position. Once the pressure dissipates, the swing flaps 210 can return to the open position, allowing for the resumption of normal airflow. This ability to be moved between positions enables the swing flaps 210 to effectively manage the internal environment of the switchgear enclosure 200, enhancing both performance and safety.

The swing flaps 210 can be implemented as one or multiple swing flaps 210, such as two, three, four, or more swing flaps 210. In some cases, each swing flap 210 is positioned at a respective opening in the switchgear enclosure 200. In other configurations, two or more swing flaps 210 can be positioned at the same opening to manage airflow more effectively. For example, they can collectively close or block the opening when in the closed position. In some cases, some or all of the swing flaps 210 are mechanically linked to move dependently, facilitating synchronized movement during fault conditions. This mechanical linkage can be achieved through rods, gears, cables, etc. to facilitate synchronized movement. For instance, a rod and lever system can be used so that when one swing flap 210 begins to close, it pulls the rod, causing adjacent swing flaps 210 to close as well. Alternatively, gears attached to the hinges of each swing flap 210 can be meshed together, ensuring that rotating one gear (and swing flap 210) can cause all connected gears (and swing flaps 210) to rotate in unison.

The airflow components 220 can provide cooling and ventilation within the switchgear enclosure 200. In some cases, the airflow components 220 can be fans, blowers, or other mechanisms designed to move air efficiently. The airflow components 220 can be strategically placed within the switchgear enclosure 200 to aid in the dissipation of heat, such as that generated by the electrical components 230.

The airflow components 220 can include one or multiple airflow components 220, such as two, three, four, or more airflow components 220. In some cases, one or more of the airflow components 220 can be active, while one or more can be inactive at a time. For example, in a configuration with two airflow components 220, a first airflow component can be ON, and a second airflow component can be OFF. The airflow generated by the first airflow component can move air out through the opening of the second airflow component, causing the fan of the second airflow component to move without being powered. Such a theme can be perpetuated when the system includes any number of airflow components 220. For example, an equal number of airflow components 220 can be ON as OFF. In some cases, the airflow components 220 are distributed as ON or OFF to achieve a balanced airflow, which may indicate a non-equal number of airflow components 220 being ON and OFF. In some cases, rather than being OFF, one or more airflow components may be ON but oriented in a reverse direction to blow air out.

In some configurations, the airflow components 220 can be controlled by a central system to synchronize their operation. For instance, if one airflow component 220 increases its speed in response to rising temperatures, the other components can adjust accordingly to maintain balanced cooling. As a non-limiting example, the airflow components 220 can be configured to respond to fault conditions. For instance, during an arc fault, the generated pressure and heat can trigger the airflow components 220 to increase their operation to expel hot air and hazardous byproducts more rapidly. In some cases, the airflow components 220 may turn off during a fault condition because the swing flaps 210 close in response to the fault condition, preventing further airflow. This coordinated response can improve the overall effectiveness of the thermal management system 250, allowing the switchgear enclosure 200 to maintain safe operating temperatures under most conditions.

The airflow components 220 can be positioned at various locations within the switchgear enclosure 200 to aid in cooling. In some configurations, a single airflow component 220 can be placed near the top of the enclosure to push air downwards, while another can be positioned at the bottom to facilitate the expulsion of hot air. In other configurations, multiple airflow components 220 can be distributed throughout the enclosure to ensure even cooling and prevent hotspots.

The airflow components 220 can be positioned at various locations within the switchgear enclosure 200 to aid in cooling. In embodiments where the thermal management system 250 includes multiple airflow components 220, the positioning of the airflow components 220 can vary. In some configurations, the airflow components 220 can be disposed at substantially the same vertical level, being laterally aligned within the switchgear enclosure 200. For example, a first airflow component 220 and a second airflow component 220 can be disposed adjacent to each other at or near a top portion of the switchgear enclosure 200. In other configurations, the airflow components 220 can be disposed at different vertical levels. For instance, one airflow component 220 can be positioned near the top portion of the enclosure to direct air downwards, while another airflow component 220 can be positioned near the upper middle, middle, lower middle, or bottom portion to facilitate the expulsion of hot air. This strategic and varied placement of the airflow components 220 can facilitate effective cooling and mitigate the formation of hotspots within the switchgear enclosure 200.

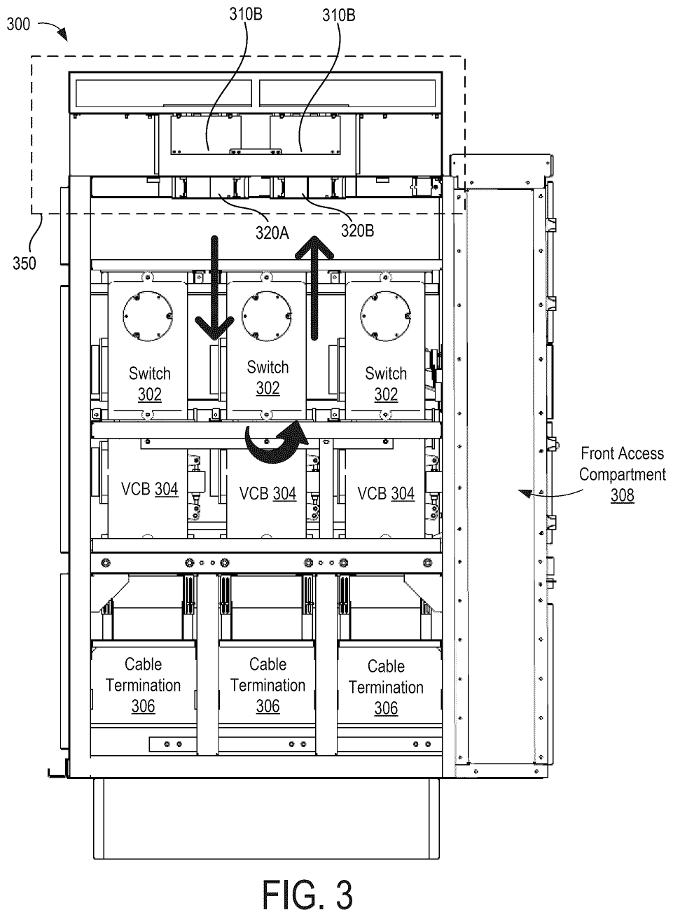

FIG. 3 illustrates a side internal view of an implementation of an example thermal management system 350 within the switchgear enclosure 300. In this view, a side panel of the switchgear enclosure 300 is removed to reveal the internal components and airflow paths. The switchgear enclosure 300 houses electrical components 330 that can be sources of heat. The switchgear enclosure 300 can include one or more switches 302, one or more vacuum circuit breakers (VCB) 304, and/or one or more cable terminations 306. The switchgear enclosure 300 can include a front access compartment 308. The thermal management system 350 includes two swing flaps 310A, 310B, and two airflow components 320A, 320B, each positioned near the top of the switchgear enclosure 300.

In this example, only the first airflow component 320A is operational, while the second airflow component 320B is OFF and serves as a redundant airflow source, should the first airflow component 320A fail. The first airflow component 320A is configured to push air downwards into the switchgear enclosure 300, creating a downward airflow path indicated by the arrows. This airflow path directs cool air towards heat-generating electrical components 330. The cool air enters the switchgear enclosure 300 through the first swing flap 310A and flows downward, absorbing heat from the electrical components 330. The air follows a path from the first airflow component 320A, circulating around the electrical components 330, and then moves upwards towards the second airflow component 320B. The air flow through an opening associated with the second airflow component 320B and exits through the second swing flap 310B. In some cases, the second airflow component 320B can function as an exhaust fan, facilitating the exit of air from the switchgear enclosure 300.

In some embodiments, either of the airflow components 320A and 320B can be implemented simply as openings or holes. These openings facilitate airflow through the enclosure, allowing cool air to enter and hot air to exit, thereby managing the internal temperature effectively. This approach simplifies the design by eliminating the need for complex airflow mechanisms, relying instead on strategically placed holes to ensure adequate ventilation and heat dissipation within the enclosure 300.

Although FIG. 3 illustrates the swing flaps 310A, 310B in a general horizonal state when in the closed position, in some cases, one or more of the swing flaps 310A, 310B can be generally vertical when in the closed position. For example, such flaps may be located on the sides of the switchgear enclosure 300. These vertical flaps can be positioned at respective openings on the sides of the switchgear enclosure 300, allowing them to move between open and closed positions to manage airflow effectively. Other orientations can also be used, providing flexibility in design to ensure efficient heat dissipation and maintain necessary safety measures against arc faults.

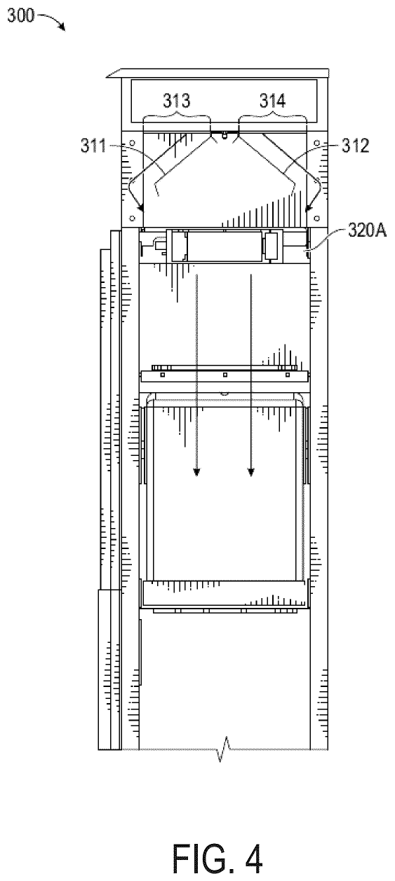

FIG. 4 illustrates a front internal view of the switchgear enclosure 300. This view shows the arrangement of only the first airflow component 320A and the first swing flap 310A, as they are positioned in front of the second airflow component 320B and the second swing flap 310B, which are located behind and not visible in this perspective. This positioning highlights the airflow path facilitated by the first airflow component 320A and the first swing flap 310A.

The first swing flap 310A includes two individual flaps 311, 312, each pivotally connected to the switchgear enclosure 300. In this example, the angle, Z, of the flaps 311, 312 is approximately 35 degrees relative to a plane of the openings 313, 314, in the normal operating position. However, the angle, Z, may vary across embodiments, such as between about 20 to about 40 degrees. As shown, there is a respective opening 313, 314 in the switchgear enclosure 300 near the pivot point where each flap 311, 312 attaches to the switchgear enclosure 300. These openings 313, 314 allow for air to flow into and/or out of the switchgear enclosure 300, around the respective flap 311, 312.

As indicated by the arrows, incoming air flows through the openings 313, 314, around the angled flaps 311, 312, and then into the first airflow component 320A. In this way, the airflow path from the openings 313, 314 to the first airflow component 320A is not a direct line. The airflow would exit through a similar path. This indirect path can aid in retaining arc fault byproducts within the switchgear enclosure 300. For example, the arc fault byproducts would have to navigate around the flaps 311, 312 to exit, which delays the escape of the arc fault byproducts from the switchgear enclosure 300 and provides additional time for the swing flaps 310A to close, thereby containing the arc fault byproducts more effectively.

This arrangement facilitates the creation of a non-linear airflow path. The non-linear airflow path can delay the escape of arc fault byproducts from the switchgear enclosure 300 by requiring the byproducts to navigate around the flaps 311, 312, providing additional time for the swing flap 310A to move to the second position in response to pressure from the arc fault, thereby improving containment of the arc fault byproducts.

### Terminology

Although this disclosure has been described in the context of certain embodiments and examples, it will be understood by those skilled in the art that the disclosure extends beyond the specifically disclosed embodiments to other alternative embodiments and/or uses and obvious modifications and equivalents thereof. In addition, while several variations of the embodiments of the disclosure have been shown and described in detail, other modifications, which are within the scope of this disclosure, will be readily apparent to those of skill in the art. It is also contemplated that various combinations or sub-combinations of the specific features and aspects of the embodiments may be made and still fall within the scope of the disclosure. For example, features described above in connection with one embodiment can be used with a different embodiment described herein and the combination still fall within the scope of the disclosure. It should be understood that various features and aspects of the disclosed embodiments can be combined with, or substituted for, one another in order to form varying modes of the embodiments of the disclosure. Thus, it is intended that the scope of the disclosure herein should not be limited by the particular embodiments described above. Accordingly, unless otherwise stated, or unless clearly incompatible, each embodiment of this invention may include, additional to its essential features described herein, one or more features as described herein from each other embodiment of the invention disclosed herein.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, 0.1 degree, or otherwise.

Any terms generally associated with relative positions, such as “above,” “below,” “top,” “bottom,” “left,” “right,” “front,” “back,” or any derivatives or similar types of terms, are intended to be used to designate relative positions and directions with respect to the described object, component, or system. These terms are not intended to be limiting and may encompass different orientations depending on the perspective of the object, component, or system described. For example, “above” or “below” should be understood to mean a higher or lower position relative to another part, respectively, regardless of the absolute orientation of the system.

Any terms generally associated with directions, such as “horizontal,” “vertical,” “lateral,” “longitudinal,” “upward,” “downward,” “inward,” “outward,” “leftward,” “rightward,” or any derivatives or similar types of terms, are intended to be used to designate any corresponding directional relationship in any spatial orientation. These terms are not intended to be limiting to any specific orientation or direction. For instance, “horizontal” can refer to a direction parallel to a reference plane, which can vary depending on the system's configuration.

Any terms generally associated with angles, such as “acute,” “obtuse,” “right,” “perpendicular,” “parallel,” “angular,” or any derivatives or similar types of terms, are intended to be used to describe angular relationships between components or features. These terms are not limited to any specific angular measurements unless explicitly defined. For example, “perpendicular” can refer to any two lines or planes that intersect at an angle close to 90 degrees, subject to manufacturing tolerances.

Any terms generally associated with geometric shapes and dimensions, such as “length,” “width,” “height,” “depth,” “thickness,” “cross-section,” “radius,” “diameter,” “circumference,” or any derivatives or similar types of terms, are intended to be used to describe any corresponding dimension or geometry. These terms are not limited to specific geometric shapes unless explicitly stated. For example, “length” can refer to any linear dimension along any axis or direction, and “diameter” can refer to the cross-sectional width of any shape.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

What is claimed is:

1. A thermal management system for a switchgear enclosure configured to house electrical components, comprising:
a swing flap positioned at an opening on the switchgear enclosure, the swing flap configured to move between a first position in which the opening is unobstructed by the swing flap to thereby allow airflow through the opening, and a second position in which the opening is obstructed by the swing flap to thereby restrict airflow through the opening; and
first and second airflow components, each positioned between the electrical components and the swing flap, wherein at least one of the first or second airflow components facilitate an introduction of airflow into the switchgear enclosure through the opening, passage of the airflow through the electrical components, and exit of the airflow from the switchgear enclosure through the opening,
wherein the swing flap is configured to move to the second position responsive to pressure generated by an arc fault within the switchgear enclosure, thereby reducing a likelihood of escape of arc fault byproducts from the switchgear enclosure.

2. The system of claim 1, wherein the swing flap is normally biased to the first position by gravitational force, thereby allowing airflow through the opening under normal operating conditions.

3. The system of claim 1, wherein the exit of the airflow from the switchgear enclosure through the opening occurs via another airflow component.

4. The system of claim 1, wherein the swing flap is normally biased to a second-position, and wherein the swing flap is configured to be pulled to the first position by the airflow generated by the first and second airflow components, thereby allowing airflow through the opening under normal operating conditions.

5. The system of claim 1, wherein the swing flap comprises a first swing flap and a second swing flap, and the opening comprises a first opening and a second opening, wherein the first swing flap is positioned at the first opening and the second swing flap is positioned at the second opening.

6. The system of claim 5, wherein the first airflow component is mechanically aligned with the first swing flap and the first opening, and the second airflow component is mechanically aligned with the second swing flap and the second opening.

7. The system of claim 5, wherein the first airflow component is configured to facilitate the introduction of airflow into the switchgear enclosure through the first opening, and the second airflow component is configured to facilitate the exit of airflow from the switchgear enclosure through the second opening.

8. The system of claim 5, wherein the first and second openings are sized to maintain a balanced inlet-to-outlet airflow ratio, thereby reducing a likelihood of pressure buildup or backpressure within the switchgear enclosure.

9. The system of claim 5, wherein the first and second swing flaps are mechanically linked to move dependently, facilitating synchronized movement into the second position.

10. The system of claim 5, wherein the first airflow component comprises a fan configured to introduce the airflow into the switchgear enclosure and the second airflow component comprises an aperture configured to allow the airflow to pass from the electrical components to the second opening.

11. The system of claim 1, wherein in the first position the swing flap is oriented at an angle between 20 and 40 degrees relative to a plane of the opening.

12. The system of claim 1, wherein the switchgear enclosure has a continuous current rating of up to 3150 A.

13. The system of claim 1, wherein the switchgear enclosure has a width between 500 mm and 800 mm.

14. The system of claim 1, wherein the system is a gas insulated switchgear (GIS) system, wherein the electrical components comprise at least one heat producing component positioned within the switchgear enclosure, and wherein the at least one heat producing component comprises a vacuum interrupter, a copper conductor, or a canted contact spring.

15. The system of claim 1, further comprising a third airflow component positioned between the electrical components and the swing flap, wherein the third airflow component further facilitates the introduction of airflow into the switchgear enclosure through the opening, the passage of the airflow through the electrical components, and the exit of the airflow from the switchgear enclosure through the opening.

16. A thermal management system for a switchgear enclosure configured to house electrical components, comprising:
a plurality of swing flaps positioned at corresponding openings on the switchgear enclosure, each swing flap being movable between a first position, which allows unobstructed airflow through its respective opening, and a second position, which restricts airflow through its respective opening, the swing flaps being normally in the first position;
a plurality of airflow components positioned between the electrical components and the swing flaps, the airflow components facilitating an entry of airflow into the switchgear enclosure through a first opening of the openings, directing the airflow through the electrical components, and facilitating an exit of the airflow from the switchgear enclosure through a second opening of the openings;
wherein the swing flaps are mechanically linked such that each swing flap moves in unison to the second position in response to pressure generated by an arc fault within the switchgear enclosure, thereby reducing a likelihood of arc fault byproducts escaping from the switchgear enclosure.

17. The system of claim 16, wherein only one of the plurality of airflow components is active at a time to introduce airflow into the switchgear enclosure.

18. A thermal management system for a switchgear enclosure including an opening for airflow and configured to house electrical components, comprising:
at least one airflow component positioned to facilitate introduction and movement of the airflow within the switchgear enclosure;
at least one swing flap positioned between the opening and the airflow component, the swing flap configured to move between a first position in which the swing flap is positioned to create a non-linear airflow path from the opening to the airflow component such that the airflow is directed around the swing flap, and a second position in which the opening is obstructed by the swing flap to thereby restrict airflow through the opening,
wherein the non-linear airflow path delays escape of arc fault byproducts from the switchgear enclosure by requiring the byproducts to navigate around the swing flap, providing additional time for the swing flap to move to the second position in response to pressure from the arc fault.

19. The system of claim 18, wherein the swing flap is pivotally connected to the switchgear enclosure proximate the opening, and is configured to pivot between the first and second positions, and wherein the swing flap is in the first position under normal operating conditions.

20. The system of claim 19, wherein the swing flap is oriented at an angle between about 20 degrees and about 40 degrees relative to a plane of the opening.
